(19) United States
(12) Patent Application Publication
(10) Pub. No.: US 2008/0225610 A1
(43) Pub. Date: Sep. 18, 2008

(54) Write driver of semiconductor memory device and driving method thereof

(75) Inventor: Khil-Ohk Kang, Kyoungki-do (KR)

Correspondence Address: MCDERMOTT WILL & EMERY LLP, 600 13TH STREET, N.W., WASHINGTON, DC, 20005-3096, US

(73) Assignee: HYNIX SEMICONDUCTOR INC.

(21) Appl. No.: 12/003,683

(22) Filed: Dec. 31, 2007

(30) Foreign Application Priority Data
Mar. 12, 2007 (KR) 2007-0023983

(51) Int. Cl. G11C 7/00

(52) U.S. Cl. 365/189.11

(57) ABSTRACT

A write driver of a semiconductor memory device over drives a local input/output line at a write operation in order to transmit data provided in a global input/output line to a core area at a stable voltage level. Therefore the write driver charges a stable voltage level corresponding to data inputted at the write operation in a cell capacitor. The write driver includes a pull-up/pull-down driver for pull-up/pull-down driving a second data line depending on data loaded on a first data line, a pulse generation circuit for generating pull-up over driving pulses activated for a predetermined time period at the initial time of an interval that the second data line is pull-up driven, and an over driver for pull-up driving the second data line by an over driving voltage higher than a pull-up voltage of the pull-up/pull-down driver in response to the pull-up over driving pulses.

### CROSS-REFERENCE TO RELATED APPLICATIONS

This application invention claims priority to Korean patent application number. 10-2007-0023983, filed on Mar. 12, 2007, which is incorporated by reference in its entirety.

### BACKGROUND OF THE INVENTION

The present subject matter relates to semiconductor design technologies, particularly to a write driver for the semiconductor memory device and a driving method thereof, and more particularly to an over driving operation of the write driver.

A semiconductor memory device such as DDR SDRAM (Double Data Rate Synchronous DRAM) is generally provided with a plurality of memory banks, each of which has a set of memory cells composed of a cell transistor and a cell capacitor. Here, an area where the memory banks are arranged is called a core area and an area which is configured to input/output data to/from the memory banks is called a peri area. In a write operation, data provided from the peri area is inputted to the core area through a write driver arranged at the boundary of the core area. Meanwhile, in a read operation, data to be outputted is provided to the peri area through an input/output sense amplifier placed at the boundary of the core area. Generally, a data line which is connected between data input/output pins and the write driver or the input/output sense amplifier is called a GIO (Global Input/Output) line and a data line which is connected between the write driver or the input/output sense amplifier and to the inside of the core area is called an LIO (Local Input/Output) line.

FIG. 1 illustrates a schematic circuit diagram of a conventional write driver.

The write driver includes a pull-up/pull-down driver 100 and a precharger 120. The pull-up/pull-down driver 100 pull-up/pull-down drives local input/output lines LIO and /LIO in response to first and second driving control signals CTR_PD1 and CTR_PD2. The precharger 120 precharges the local input/output lines LIO and /LIO in response to a reset signal RST. Here, the first and the second driving control signals CTR_PD1 and CTR_PD2 are signals for pull-up/pull-down driving the local input/output lines LIO and /LIO depending on data applied to a global input/output line (not shown), and the reset signal RST is a signal enabled at the time of precharging operation of the local input/output lines LIO and /LIO.

In general, the precharging operation is a preparation process which is performed before the write operation of the write driver. The pull-up/pull-down driver 100 is deactivated in response to the first and the second driving control signals CTR_PD1 and CTR_PD2 having a logic low level while the reset signal RST is enabled and the local input/output lines LIO and /LIO are precharged to the voltage level of a core voltage end VCORE (hereinafter, “core voltage”).

After that, in the write operation of the write driver, the reset signal RST is deactivated and the pull-up/pull-down driver 100 is driven by the data loaded on the global input/output line. For convenience of explanation, if it is first assumed that in case the data applied to the global input/output line is logic low, the first driving control signal CTR_PD1 becomes logic high and the second driving control signal CTR_PD2 becomes logic low, the positive local input/output line LIO is pull-down driven to the voltage level of a ground voltage end VSS (hereinafter, “ground voltage”) by the first driving control signal CTR_PD1 and the negative local input/output line /LIO is pull-up driven to the core voltage by the second driving control signal CTR_PD2. On the contrary, if it is assumed that in case the data applied to the global input/output line is logic high, the first driving control signal CTR_PD1 becomes logic low and the second driving control signal CTR_PD2 becomes logic high, the positive local input/output line LIO is pull-up driven to the core voltage and the negative local input/output line /LIO is pull-down driven to the ground voltage. As a result, the write driver drives the local input/output line LIO or /LIO by using the core voltage depending on the data applied to the global input/output line wherein the data is forwarded to the core area and then stored in a cell capacitor.

On the other hand, recent semiconductor memory devices have been developed to meet the needs of low power consumption together with the integration and speed up thereof. As one solution for low power consumption, there is a recent tendency that the level of an external voltage supplied from outside is gradually decreasing. Due to this, the level of a core voltage which is generated by down-converting the external voltage is also decreasing. Under the circumstances, the driving power of the pull-up/pull-down driver 100 for driving the local input/output line LIO or /LIO has nothing but to be weakened. Thus, when driving the local input/output line LIO or /LIO based on the data loaded on the global input/output line, the core voltage is insufficient, thereby making a voltage level lower than a preset voltage level charged in the cell capacitor.

In addition, in case of DDR2 SDRAM, ×16 data option is possible and 4-bit prefetch method is used. Therefore, the semiconductor memory device is provided with 64 write drivers, which are equivalent to multiplication of the data option 16 and prefetch number 4. For this reason, in case 64 write drivers perform a pull-up driving operation at a time, the core voltage is insufficient, thereby also causing malfunctions mentioned above. This becomes more serious as the semiconductor memory device is developed. For example, for DDR3 SDRAM, ×16 data option is possible and 8-bit prefetch method is used, which will require 128 write drivers and make this problem more serious.

As described above, there may be a problem that the voltage level lower than the preset voltage level is charged in the cell capacitor. This problem may cause the loss of data stored in the memory cell, and although there is no data loss, the refresh operation of the memory cell may not be normally done due to the low voltage level charged in the cell capacitor.

### SUMMARY OF THE INVENTION

Embodiments of the present invention are directed to providing a write driver of a semiconductor memory device for over driving a local input/output line at a write operation in order to transmit data provided in a global input/output line to a core area at a stable voltage level. Therefore the write driver of the present invention stably and reliably operates to charge a stable voltage level corresponding to data inputted at the write operation in a cell capacitor.

In one embodiment, a write driver for a semiconductor memory device includes a pull-up/pull-down driver for pull-up/pull-down driving a second data line depending on data loaded on a first data line, a pulse generation circuit for generating pull-up over driving pulses activated for a predetermined time period at the initial time of an interval that the second data line is pull-up driven, and an over driver for pull-up driving the second data line by an over driving voltage higher than a pull-up voltage of the pull-up/pull-down driver in response to the pull-up over driving pulses.

In another embodiment, a method for driving a write driver of a semiconductor memory device includes pull-up driving a second data line depending on data loaded on a first data line, wherein the second data line are over driven by a predetermined time period at the initial time of an interval that the second data line is pull-up driven, and normally driving the second data line during the internal after over driving the second data line.

### BRIEF DESCRIPTION OF THE DRAWINGS

FIG. 1 illustrates a schematic circuit diagram of a conventional write driver.

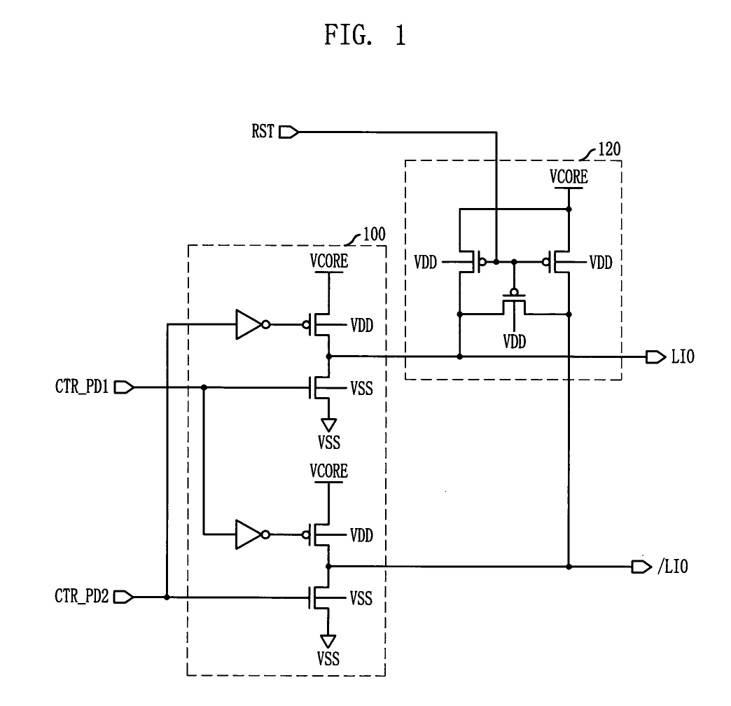

FIG. 2 is a schematic circuit diagram of a write driver in accordance with a first embodiment of the present invention.

FIG. 3 is a schematic circuit diagram of a write driver in accordance with a second embodiment of the present invention.

FIG. 4 is a signal timing diagram showing the comparison of a voltage level of the conventional local input/output line and that of the local input/output line of the present invention in terms of time.

### DESCRIPTION OF SPECIFIC EMBODIMENTS

As will be described in detail below, the present invention is further provided with an over driver for over-driving local input/output lines using an external voltage for a predetermined time period at the initial time when the local input/output lines are pull-up driven. Thus, the present invention can improve data loss phenomenon and refresh operation of memory cell caused by failure to charge a stable voltage level in a capacitor due to insufficient voltage supplied to the local input/output lines during write operation.

Hereinafter, preferred embodiments of the present invention will be described in detail with reference to the accompanying drawings so that those skilled in the art can readily carry out the invention.

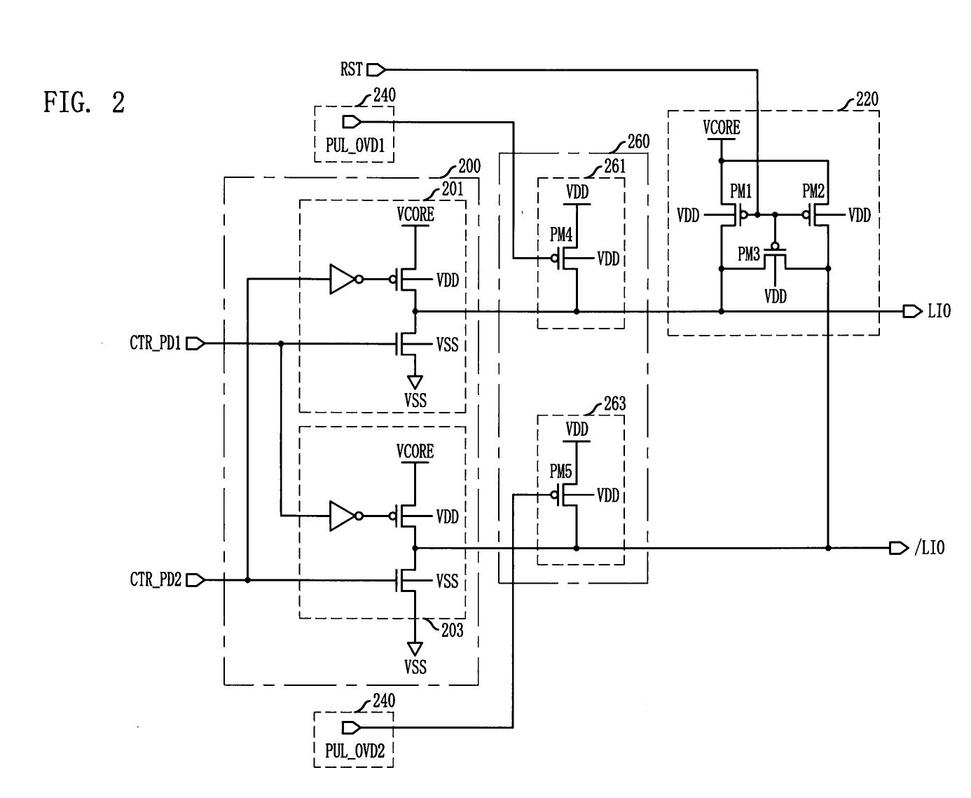

FIG. 2 is a schematic circuit diagram of a write driver in accordance with a first embodiment of the present invention. Referring to FIG. 2, the write driver of the present invention includes a pull-up/pull-down driver 200, pulse generators 240 and an over driver 260.

The pull-up/pull-down driver 200 pull-up/pull-down drives local input/output lines LIO and /LIO in response to first and second driving control signals CTR_PD1 and CTR_PD2. The pulse generators 240 generates pull-up over driving pulses PUL_OVD1 and PUL_OVD2 activated for a predetermined time period at the initial time of a pull-up interval of the local input/output lines LIO and /LIO. The over driver 260 pull-up drives the local input/output lines LIO and /LIO to the voltage level of an external voltage end VDD in response to the pull-up over driving pulses PUL_OVD1 and PUL_OVD2. In addition, the present invention may further include a precharger 220 for precharging the local input/output lines LIO and /LIO in response to a reset signal RST. Since the circuit configuration of the pull-up/pull-down driver 200 and the precharger 220 will be apparent to those skilled in the art, a concrete description thereof will be omitted here.

Here, the first and the second driving control signals CTR_PD1 and CTR_PD2 are signals for pull-up/pull-down driving the local input/output lines LIO and /LIO based on data applied to a global input/output line (not shown), and the reset signal RST is a signal activated during a precharging operation of the local input/output lines LIO and /LIO. In general, the precharging operation is a preparation process which is performed before a write operation of the write driver. The pull-up/pull-down driver 200 is deactivated in response to the first and the second driving control signals CTR_PD1 and CTR_PD2 having a logic low level during an interval that the reset signal RST is activated and the local input/output lines LIO and /LIO are precharged to the voltage level of a core voltage end VCORE.

The following is a brief description for the components, starting from the pull-up/pull-down driver 200.

The pull-up/pull-down driver 200 is provided with a first driver 201 for pull-up/pull-down driving the positive local input/output line LIO in response to the first and the second driving control signals CTR_PD1 and CTR_PD2, and a second driver 203 for pull-up/pull-down driving the negative local input/output line /LIO in response to the first and the second driving control signals CTR_PD1 and CTR_PD2.

The precharger 220 is provided with three PMOS transistors PM1, PM2 and PM3 for precharging the positive and the negative local input/output lines LIO and /LIO in response to the reset signal RST.

The pulse generators 240 generate the pull-up over driving pulses PUL_OVD1 and PUL_OVD2 in response to signals corresponding to data loaded on the global input/output line. That is, the pulse generators 240 can generate the pull-up over driving pulses PUL_OVD1 and PUL_OVD2 activated for a predetermined time period in response to signals corresponding to data, for example, the first and the second driving control signals CTR_PD1 and CTR_PD2 at the time of a write operation. Here, it is preferable that any one of the pull-up over driving pulses PUL_OVD1 and PUL_OVD2 is activated depending on the data put on the global input/output line. Details thereof will be given later.

The over driver 260 is provided with a third driver 261 for pull-up driving the positive local input/output line LIO in response to the first pull-up over driving pulse PUL_OVD1, and a fourth driver 263 for pull-up driving the negative local input/output line /LIO in response to the second pull-up over driving pulse PUL_OVD2. Here, the third driver 261 is composed of a first PMOS transistor PM4 whose source-drain is connected between the external voltage end VDD and the positive local input/output line LIO and gate receives the first pull-up over driving pulse PUL_OVD1. And, the fourth driver 263 is composed of a second PMOS transistor PM5 whose source-drain is connected between the external voltage end VDD and the negative local input/output line /LIO and gate takes the second pull-up over driving pulse PUL_OVD2.

Thus, in write operation of the write driver, the reset signal RST is deactivated and the pull-up/pull-down driver 200 and the over driver 260 are driven in response to the data loaded on the global input/output line. For convenience of explanation, if it is assumed that in case the data applied to the global input/output line is logic low, the first driving control signal CTR_PD1 becomes logic high and the second driving control signal CTR_PD2 becomes logic low, the positive local input/output line LIO is pull-down driven to the ground voltage by the first driver 201 and the negative local input/output line /LIO is pull-up driven to the core voltage by the second driver 203. Further, the second pull-up over driving pulse PUL_OVD2 becomes a pulse signal activated to logic low by a predetermined time period at the initial time of a pull-up interval of the pull-up/pull-down driver 200 and the first pull-up over driving pulse PUL_OVD1 becomes a signal deactivated to logic high. Thus, the fourth driver 263 is activated, and pull-up drives the negative local input/output line /LIO. That is, the second PMOS transistor PM5 is turned on, thereby pull-up driving the negative local input/output line /LIO to the voltage level of the external voltage end VDD (hereinafter, “external voltage”).

On the contrary, if it is assumed that in case the data applied to the global input/output line is logic high, the second driving control signal CTR_PD2 becomes logic high and the first driving control signal CTR_PD1 becomes logic low, the negative local input/output line /LIO is pull-down driven to the ground voltage by the second driver 203 and the positive local input/output line LIO is pull-up driven to the core voltage by the first driver 201. Further, the first pull-up over driving pulse PUL_OVD1 becomes a pulse signal activated to logic low by a predetermined time period at the initial time of a pull-up interval of the pull-up/pull-down driver 200 and the second pull-up over driving pulse PUL_OVD2 becomes a signal deactivated to logic high. Thus, the third driver 261 is activated, and pull-up drives the positive local input/output line LIO. That is to say, the first PMOS transistor PM4 is turned on, thereby pull-up driving the positive local input/output line LIO to the external voltage.

In other words, the third driver 261 is activated for a predetermined time period at the initial time of a pull-up interval of the first driver 201, thereby over driving the positive local input/output line LIO, and the fourth driver 263 is activated for a predetermined time period at the initial time of a pull-up interval of the second driver 203, thereby over driving the negative local input/output line /LIO.

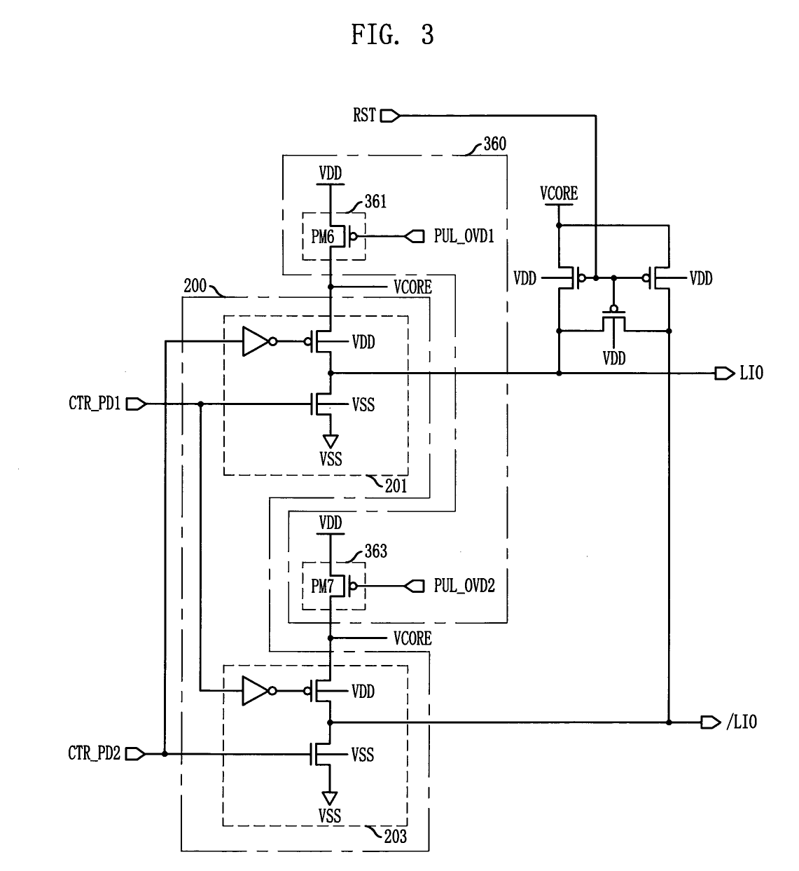

FIG. 3 is a schematic circuit diagram of a write driver in accordance with a second embodiment of the present invention, wherein like reference numerals designate like components.

Referring to FIGS. 2 and 3, a connection node of an over driver 360 of FIG. 3 is different from that of FIG. 2. In case of the over driver 360 depicted in FIG. 3, the core voltage end VCORE which is a pull-up power supply voltage end of the pull-up/pull-down driver 200 is driven by the external voltage by a predetermined time period at the initial time of a pull-up interval of the local input/output lines LIO and /LIO.

In the over driver 360, a fifth driver 361 which plays the same role as the third driver 261 is composed of a third PMOS transistor PM6 whose source-drain is connected between the external voltage end VDD and the power supply voltage end of the first driver 201 and gate receives the first pull-up over driving pulse PUL_OVD1. Further, a sixth driver 363 which plays the same role as the fourth driver 263 is composed of a fourth PMOS transistor PM7 whose source-drain is connected between the external voltage end VDD and the power supply voltage end of the second driver 203 and gate takes the second pull-up over driving pulse PUL_OVD2. The first and the second pull-up over driving pulses PUL_OVD1 and PUL_OVD2 may be signals identical to those of FIG. 2. The operation description of FIG. 3 is obvious to those skilled in the art, and therefore, it will be omitted here.

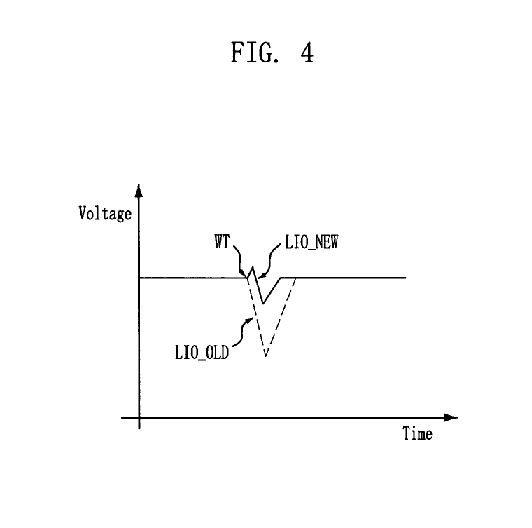

FIG. 4 is a signal timing diagram showing the comparison of a voltage level of the conventional local input/output line LIO_OLD and that of the local input/output line LIO_NEW of the present invention in terms of time. For convenience of explanation, it is assumed and explained that logic high data is provided to the core area through the positive local input/output line LIO in response to a write command WT after precharging.

Referring to FIG. 4, the voltage level of the conventional local input/output line LIO_OLD becomes decreased when the data is fed to the core area. By the way, in case of using low power semiconductor memory device, the core voltage as well as the external voltage are lowered, thereby making an insufficient voltage supplied to the core area. In contrast, the local input/output line LIO_NEW in accordance with the present invention can supply a sufficient voltage to the core area because it is over driven even if the low power semiconductor memory device is used. As a result, a stable voltage level can be charged in the cell capacitor.

As described above, the write driver of the semiconductor memory device in accordance with the present invention pull-up drives the corresponding local input/output line LIO or /LIO based on data loaded on the global input/output line, wherein the local input/output line LIO or /LIO is over driven by a predetermined time period at the initial time of the pull-up driving interval and then normally driven after that. Here, the normal driving means that the positive and the negative local input/output lines LIO and /LIO are pull-up/pull-down driven depending on the data loaded on the global input/output line, while the over driving implies that corresponding one of the positive and the negative local input/output lines LIO and /LIO is pull-up driven in response to the over driving pulse (i.e., any one of PUL_OVD1 and PUL_OVD2). Further, the local input/output line (LIO or /LIO) is driven by the external voltage during the over driving, while being driven by the core voltage lower than the external voltage during the normal driving. As a result, since the local input/output line LIO is over driven, a sufficient voltage can be supplied to the core area, thereby charging a stable voltage level in the cell capacitor.

Besides, as can be seen from FIG. 4, the voltage level of the local input/output line LIO_NEW of the present invention is higher than that of the conventional input/output line LIO_OLD after supplying the data to the core area, and thus, a recovery time for returning to the original voltage level, i.e., the core voltage, becomes faster.

Even though the second embodiment of the present invention has been illustratively described with respect to a case where each core voltage end is driven by the external voltage by a predetermined time period through the use of two drivers, the present invention can also be applied to a case where one core voltage end is driven by the external voltage by a predetermined time period by using the pull-up over driving signal enabled at the time of write operation and one driver.

As described above, the present invention can prevent defectiveness of a semiconductor memory device due to an abrupt decrease of a core power supply voltage and also transmit data provided from outside to a core area at a stable voltage level. In addition, the present invention can prevent loss of data stored in a memory cell and further improve refresh operation characteristics of the memory cell.

While the present invention has been described with respect to the specific embodiments, it will be apparent to those skilled in the art that various changes and modifications may be made without departing from the spirit and scope of the invention as defined in the following claims.

What is claimed is:

1. A write driver of a semiconductor memory device, comprising:
a pull-up/pull-down driver for pull-up/pull-down driving a second data line depending on data loaded on a first data line;
a pulse generation circuit for generating pull-up over driving pulses activated for a predetermined time period at the initial time of an interval that the second data line is pull-up driven; and
an over driver for pull-up driving the second data line by an over driving voltage higher than a pull-up voltage of the pull-up/pull-down driver in response to the pull-up over driving pulses.

2. The write driver of claim 1, wherein the pull-up/pull-down driver includes:
a first driver for pull-up/pull-down driving a positive line of the second data line based on the data; and
a second driver for pull-up/pull-down driving a negative line of the second data line based on the data.

3. The write driver of claim 2, further comprising a precharger for precharging the second data line in response to a reset signal.

4. The write driver of claim 2, wherein the over driver includes:
a third driver for pull-up driving the positive line in response to a first pull-up over driving pulse; and
a fourth driver for pull-up driving the negative line in response to a second pull-up over driving pulse.

5. The write driver of claim 4, wherein the third driver is activated for the predetermined time period at the initial time of an interval that the first driver is pull-up driven.

6. The write driver of claim 4, wherein the third driver is a MOS transistor for receiving the first pull-up over driving pulse through a gate thereof, of which source and drain are connected between an over driving voltage end and the positive line.

7. The write driver of claim 4, wherein the fourth driver is activated for the predetermined time period at the initial time of an interval that the second driver is pull-up driven.

8. The write driver of claim 4, wherein the fourth driver is a MOS transistor for receiving the second pull-up over driving pulse through a gate thereof, of which source and drain are connected between an over driving voltage end and the negative line.

9. The write driver of claim 1, wherein the pulse generation circuit generates the pull-up over driver pulses in response to signals corresponding to the data loaded on the first data line.

10. The write driver of claim 4, wherein any one of the first and the second pull-up over driving pulses is activated depending on the data loaded on the first data line.

11. The write driver of claim 1, wherein the over driving voltage is an external voltage.

12. The write driver of claim 2, wherein the over driver drives the pull-up voltage end of the pull-up/pull-down driver with the over driving voltage for the predetermined time period.

13. The write driver of claim 12, wherein the over driver includes:
a fifth driver for driving the pull-up voltage end of the first driver in response to a first pull-up over driving pulse; and
a sixth driver for driving the pull-up voltage end of the second driver in response to a second pull-up over driving pulse.

14. The write driver of claim 13, wherein the fifth driver is a MOS transistor for receiving the first pull-up over driving pulse through a gate thereof, of which source and drain are connected between an over driving voltage end and the pull-up voltage end of the first driver.

15. The write driver of claim 13, wherein the sixth driver is a fourth MOS transistor for receiving the second pull-up over driving pulse through a gate thereof, of which source and drain are connected between an over driving voltage end and the pull-up voltage end of the second driver.

16. A method for driving a write driver of a semiconductor memory device, comprising:
pull-up driving a second data line depending on data loaded on a first data line, wherein the second data line are over driven for a predetermined time period at the initial time of an interval that the second data line is pull-up driven; and
normally driving the second data line during the internal after over driving the second data line.

17. The method of claim 16, wherein normally driving the second data line includes:
pull-up/pull-down driving a positive line of the second data line depending on the data loaded on the first data line; and
pull-up/pull-down driving a negative line of the second data line based on the data loaded on the first data line.

18. The method of claim 17, further comprising precharging the second data line in response to a reset signal.

19. The method of claim 17, wherein over driving the second data line includes:
pull-up driving the positive line in response to a first pull-up over driving pulse enabled by the predetermined time period; and
pull-up driving the negative line in response to a second pull-up over driving pulse enabled by the predetermined time period.

20. The method of claim 19, wherein any one of the first and the second pull-up over driving pulses is enabled depending on the data loaded on the first data line.

21. The method of claim 16, wherein over driving the second data line drives the second data line by an over driving voltage.

22. The method of claim 21, wherein the over driving voltage is an external voltage.

23. The method of claim 21, wherein normally driving the second data line drives the second data line by a voltage lower than the over driving voltage.
